(19) United States
(12) Patent Application Publication
(10) Pub. No.: US 2008/0093671 A1
(43) Pub. Date: Apr. 24, 2008

(54) Semi-Conductor Element Comprising An Integrated Zener Diode And Method For The Production Thereof

(76) Inventor: Hubert Enichlmair, Graz (AT)

Correspondence Address: Thomas Langer;Cohen Pontani Lieberman & Pavane, 551 Fifth Avenue, Suite 1210, New York, NY, 10176, US

(21) Appl. No.: 10/592,335

(22) PCT Filed: Jan. 19, 2005
(86) PCT No.: PCT/EP05/00499

§ 371 Date: Aug. 27, 2007

(30) Foreign Application Priority Data
Mar. 10, 2004 (DE) 102004011703.9

(51) Int. Cl. H01L 23/62; H01L 21/8222; H01L 27/02; H01L 29/866

(52) U.S. Cl. 257/355; 438/328; 257/E21.608; 257/E27.009; 257/E29.335

(57) ABSTRACT

In order to protect a semiconductor component against overvoltages, the steps which are used for production of bipolar transistors and CMOS structures in the semiconductor component are used for integrated parallel production of a zener diode. This has a first and a second n-doped zone, which extend between the surface of a semiconductor substrate and an n-doped buried region. The first n-doped zone is oppositely doped with p-doping in an area adjacent to the surface, and represents a p-doped region. A first contact is provided to the p-doped region, and a contact is on the other hand provided to the second n-doped zone, with the two contents forming the two connections of the zener diode.

Zener diodes are pn diodes which breakdown suddenly when a specific voltage, the so-called zener voltage, is applied in the reverse-biased direction. They are therefore normally used as voltage-limiting components, and in particular for protection of semiconductor components against overvoltages.

Electrostatic charging and, following this, electrostatic discharge phenomena (ESD) lead to short current pulses of high voltage and moderate current intensity. These ESD effects are always a problem in integrated circuits, and are particularly damaging to complementary metal-oxide semiconductors (CMOS components). CMOS structures have only a thin gate oxide and short conductive channels, which can withstand only a few tens of volts. An ESD discharge whose pulse passes through a CMOS structure can break open the gate oxide, and in consequence burn through it. Latch-up effects can also occur with thicker oxide layers. In any case, this leads to a temporary malfunction, and generally also to failure of the component.

In order to avoid ESD problems and other overvoltages, the component inputs and outputs are normally bridged by diodes, which can dissipate overvoltages via a short-circuit, without any risk to the component.

U.S. Pat. No. 5,821,572 B1 discloses an integrated semiconductor component which has a bipolar transistor, a CMOS structure and an integrated zener diode bridging the inputs. For production using a BICMOS process, which is compatible with the CMOS and bipolar structures, n-doped and p-doped regions are in this case produced in the p-doped well for the base of the npn bipolar transistor, in order to produce a pn junction for the zener diode. The production of the zener diodes is integrated in the BICMOS process.

The object of the present invention is to specify an improved semiconductor component with a fully integrated zener diode, which can be produced easily, in an integrated form and in such a manner that the zener voltage can be monitored well.

According to the invention, this object is achieved by a semiconductor component as claimed in claim 1. Advantageous refinements of the invention and a method for production of the semiconductor component are specified in further claims.

A semiconductor component according to the invention has an integrated zener diode with a new structure. A buried n-doped region is provided in a semiconductor substrate, for this purpose. At least two n-doped zones are arranged between the surface of the substrate and the buried region, and create electrically conductive paths from the surface to this buried region. In an area adjacent to the surface within the first n-doped zone, this n-doped zone is provided with opposite p-doping. A first contact is formed above the p-doped region on the surface of the substrate, and a second contact is formed above the second n-doped zone with these contacts forming the electrical connections of the zener diode.

The zener diode has a vertical structure, whose semiconductor junction is governed solely by the doping profile of the n-doped zone and p-doped region, and as a consequence of those, can be set exactly, and in a manner which allows it to be monitored well, without complex structuring and adjustment. The zener voltage, which is dependent on the doping profile, can likewise be set exactly.

The pn junction of the zener diode and the doping and in particular implantation processes which are required for this purpose are standard methods in a BICMOS process, and are thus carried out integrated with the production of the corresponding bipolar transistor structures and the CMOS structures. Neither a separate mask nor a separate method step is required for this purpose. A component according to the invention can thus be produced at low cost and has a zener voltage which can be monitored well, allowing overvoltages to be dissipated safely in the semiconductor component, and preventing overvoltages from causing damage to CMOS structures and other sensitive parts of the component.

In one advantageous geometric refinement, the first n-doped zone is arranged centrally, and is surrounded in an annular shape by the second n-doped zone, which is arranged concentrically with respect to the central, first n-doped zone. This results in a zener-diode structure whose anode connection has a high current density via the p-doped central region, and whose cathode, which is connected to the second n-doped zone, is connected with low impedance. This guarantees rapid dissipation of the overvoltage if the zener voltage is exceeded. During this process, the central contact can be deliberately degraded, resulting in this contact having a low impedance, so that it is referred to as a zener fuse. A zener fuse can be used to produce electrically programmable components which can be programmed deliberately by application of a voltage which exceeds the zener voltage to the zener diode, creating low-impedance conductive links, which were not present prior to this. If the zener voltage is monitored, the degradation can be carried out reproducibly, and can be set accurately.

A semiconductor component according to the invention has at least one vertically arranged bipolar transistor. Its collector, which is arranged in the substrate, is connected via a buried region with n-doping. A further buried region of the same configuration and/or with the same implantation depth and the same doping is also used for connection of the anode of the zener diode. In the BICMOS structure, this process can thus be used at the same time to produce the collector connection, and to produce the anode connection, of the zener diode.

The collector connection and the connection of the buried region to the surface via a conductive n-doped zone are produced together with the identical anode connection of the zener diode, which likewise has an n-doped second zone which is offset laterally with respect to the n-doped zone, and by means of which the buried region is connected to the surface, and to the contact arranged there, via a conductive path.

Furthermore, a component according to the invention has a CMOS structure whose p-channel transistor has p-doped source/drain regions, which are produced in the same step as the p-doped central region of the zener diode, and thus have the same doping strength and implantation depth.

The buried region is preferably doped with antimony. This has the advantage that the antimony doping has only a slight diffusion tendency. The buried region can thus be produced with tightly delineated doping and with a rapidly rising doping profile. This allows reliable connection of the zener diode and of the collector without the characteristics of the pn junction of the zener diode or of the collector-basic junction of the bipolar transistor being influenced or changed unacceptably by diffusion into the area of the semiconductor junction.

The first and second n-doped zones are doped with phosphorus, in the same way as the collector connection. The doping is in the form of a so-called collector sinker, in which phosphorus doping is implanted with high energy, and is then thermally driven into the buried region.

The p-doped region has flat doping relative to the n-doped zones with a high dopant content, preferably with boron being used as the p-dopant. This corresponds to the boron doping of the source/drain regions of the CMOS structure produced in the same method step. This doping is carried out with low implantation energy but with a very high dose, and this is followed by a relatively short thermal step for activation of the doping.

The invention and, in particular, the method for production of a semiconductor component according to the invention will be explained in more detail in the following text with reference to exemplary embodiments and the associated Figures. The Figures are only schematic and are not to scale, in order to assist understanding. Identical elements are annotated with the same reference symbols.

FIGS. 1 to 6 show schematic cross sections of the component during various method steps during the production process,

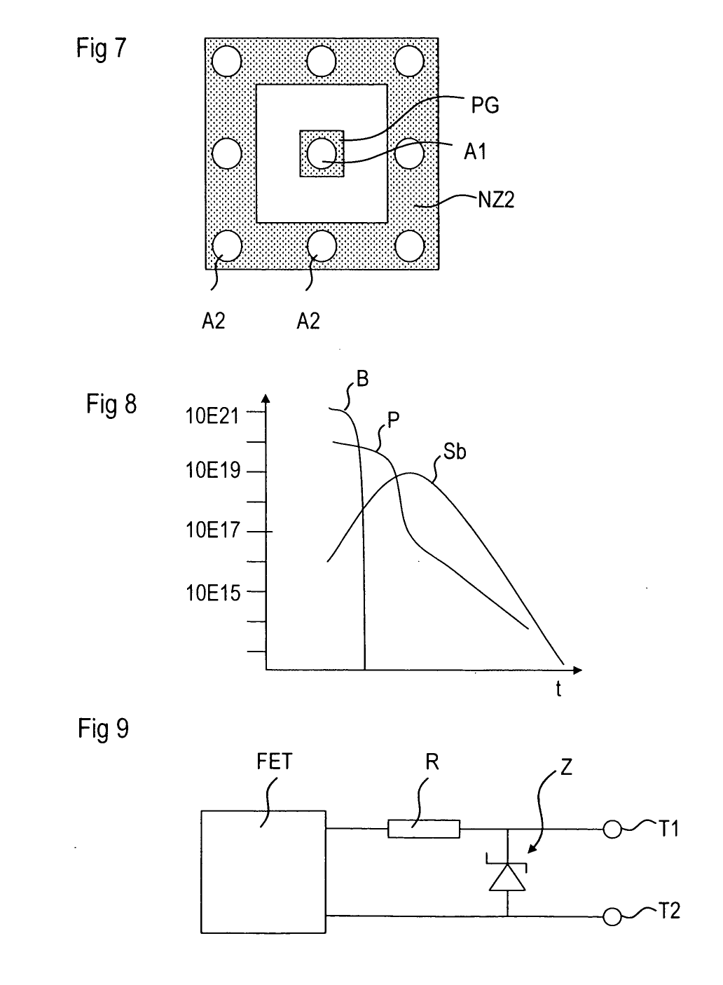

FIG. 7 shows a schematic plan view of a component,

FIG. 8 shows the distribution of the different dopants on the basis of dopant profiles, and

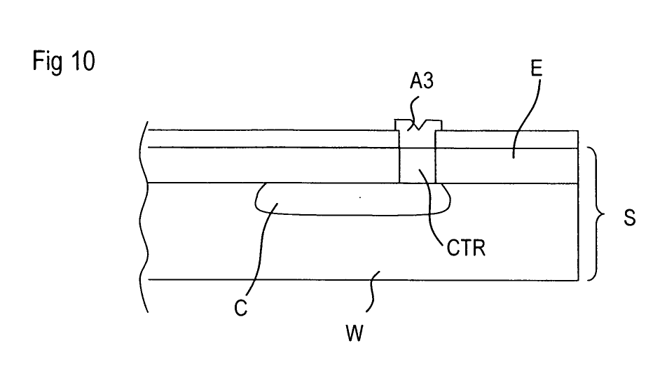

FIG. 9 shows simple schematic circuitry of a component according to the invention, with an integrated zener diode, on the basis of a circuit diagram.

A component according to the invention is manufactured at wafer level, using an integrated method. The starting point is thus a semiconductor wafer W, in particular a silicon wafer. However, semiconductor alloys may also be used, for example SiGe with a germanium content of up to 30%, for the wafer. By way of example, a silicon wafer is used which has weak p-doping of about 10¹⁶ cm⁻³. A first implantation mask M1 is applied to this wafer, in order to produce the buried regions for the bipolar transistors and the at least one zener diode at the desired points. The mask may be composed of oxide and, in particular, of field oxide. Resist masks are also suitable for large-area masking. Antimony is now implanted with a medium implantation energy level into the region PV in the areas cut out from the mask. The antimony doping is then thermally activated and driven in. FIG. 1 shows a schematic cross section through the wafer after this step.

An epitaxial layer E is then grown over the semiconductor wafer, for example a silicon layer with weak basic p-doping of about 10¹⁵ cm⁻³. The arrangement produced in this way, a schematic cross section through which is shown in FIG. 2, shows the semiconductor substrate S in which the region with the antimony doping is located underneath the epitaxial layer E, and now represents a buried region PV.

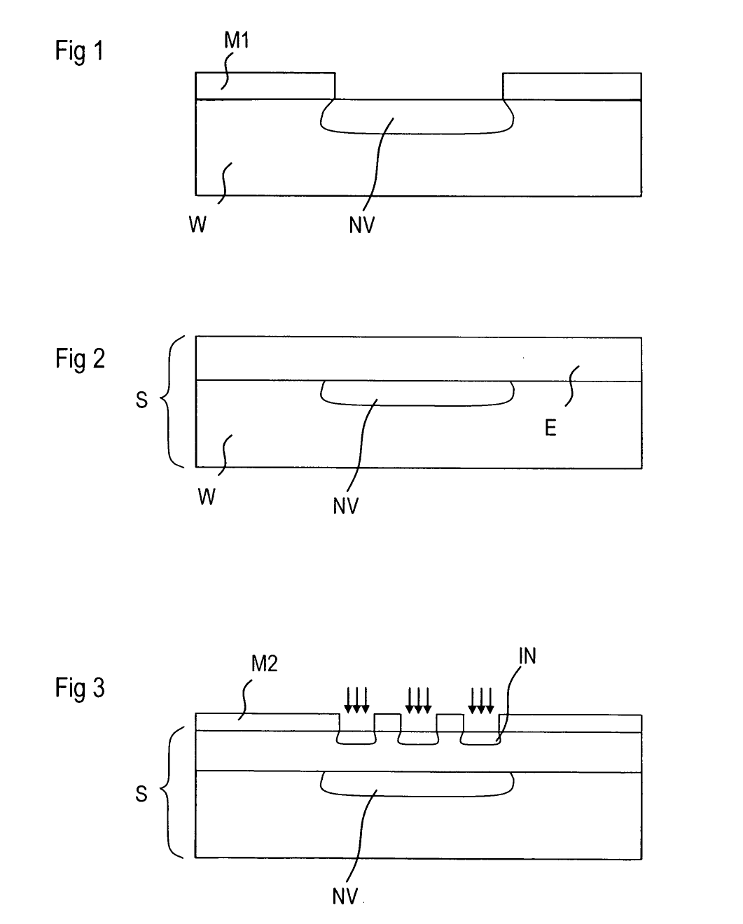

During the course of the BICMOS process, a second implantation mask M2 is produced on the substrate and has at least two openings, which are physically separated from one another, above a buried region PV. Phosphorus is now implanted with a high implantation energy and a high dose in the exposed semiconductor surface (see arrows), thus producing implanted regions IN. FIG. 3 shows the arrangement during the implantation process, in the form of a schematic cross section.

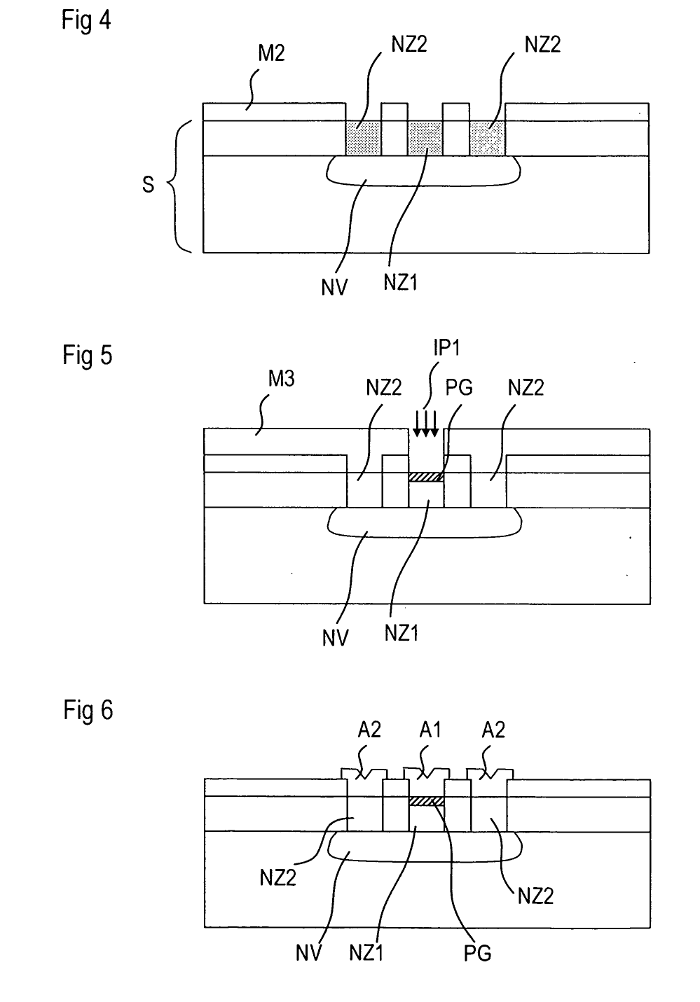

The implanted phosphorus is then driven deeper into the substrate S in a thermal step, until the n-doped zones NZ have diffused as far as the buried region PV. FIG. 4 shows the arrangement after the production of the n-doped zones NZ. The Figures show an embodiment in which a first n-doped zone NZ1 is adjacent to two second n-doped zones NZ2, which are separated from one another, with the zones all being connected to the same buried region PV.

The phosphorus implantation (which is illustrated in FIG. 3) via the implantation mask M2 in order to produce the doped zones NZ is at the same time used to simultaneously produce an identical n-doped zone, at a different point, as far as a different buried region, for a collector connection for a vertical bipolar transistor. The buried region is used as a sub-collector in the bipolar transistor. By virtue of their production process, which includes the dopant being driven in deeply, the n-doped zones are also referred to as n-sinkers, or in this specific case, as collector sinkers.

In a next step, a third implantation mask M3 is produced, which leaves an opening above the first n-doped zone NZ1 free in the area of the zener diode. A boron implantation process is then carried out with low implantation energy but with a high dose through this mask opening. The arrows IP1 in FIG. 5 show this implantation process, which leads to the production of a p-doped region PG. The boron doping is then activated, for example by means of a short thermal step at about 1000° for about 20 seconds.

The mask M3 and the boron implantation process following it are at the same time used to produce the source/drain regions at a different point, for a CMOS structure. The mask M3 has corresponding further openings for this purpose.

The connecting contacts for the p-doped region PG and for the n-doped zones NZ2 are then produced, using steps which are known per se. For this purpose, by way of example, a p-type contact-plug implantation process is carried out in a known manner over the p-doped region PG, using tungsten silicide as a connecting contact A1. Contact connections A2 for the second n-doped zone NZ2 are produced in a similar manner. FIG. 6 shows the arrangement with the completed connecting contacts A1, A2. The zener diode now comprises the pn junction between the p-doped region PG and the central, n-doped zone NZ1 underneath it. The anode of the zener diode is electrically connected via the buried region PV and the second n-doped zone NZ2.

FIG. 7 shows one particularly advantageous refinement of the p-doped region PG, which is applied over the first n-doped zone NZ1. The first n-doped zone NZ1 is produced in a central area of the zener diode, in the same way as the p-doped region PG. The second n-doped zone NZ2 surrounds this central region, at a distance from it, in an annular shape. This ensures a low-impedance connection of the anode side of the zener diode via the increased conductor cross section of the n-doped zone NZ2, which has a relatively large area. This plan view also schematically illustrates the connecting contacts A1, A2, in which case a large number of connecting contacts A2 can be provided for the second n-doped zone NZ2.

FIG. 8 shows an example of a doping profile for the zener diode in the area of the semiconductor junction of the diode. This shows the dopant content, plotted on a logarithmic scale in atoms/cm³, against the penetration depth t. The illustrated curves show the dopant distribution in the finished component for boron, phosphorus and antimony as a function of the virtual distance from the surface of the substrate, without a defined origin.

The highest dopant concentration, and also the steepest drop and thus also the most compact dopant, is the boron doping B, which also has the shallowest penetration depth. The curve P for the phosphorus doping, which is produced as a sinker, has a flatter drop because of the diffusion process, and with a medium doping level intersects the doping profile of the antimony doping Sd. The antimony doping has its maximum at the center of the buried region NV. The resultant effective overall doping leads to a sharp pn junction approximately at the intersection of the lines of the dopant content B and P. The flat p-doped region with the boron doping B has a sharply delineated penetration depth, can be monitored well by means of the driving-in conditions, and leads to a clean pn junction. The position of the pn junction and its depth in this case determine the level of the zener voltage, with the zener voltage increasing as the penetration depth of the boron doping B increases. A component according to the invention advantageously has zener diodes with zener voltages of typically 2V.

A zener diode produced in an integrated form is thus connected in the finished semiconductor component to the other semiconductor components, and in particular to the CMOS structures, such that component areas which are at risk are bridged by the zener diode, which is connected in the reverse-biased direction. FIG. 9 shows a schematic illustration of a CMOS structure FET, which is connected to a first and a second connection T1, T2 via a resistor R. In the reverse-biased direction, the zener diode Z creates a short-circuit between T1 and T2. This means that the current resulting from a suddenly occurring overvoltage can be dissipated without any damage when the zener voltage is exceeded, and the component structure FET is not damaged. Such dissipation may be provided between the inputs and outputs of the semiconductor component, between the supply voltage and an input or output or between one of the stated connections and ground, in order to dissipate overvoltage between any two of the connections mentioned, in each case. It is also possible to provide a plurality of zener diodes in one semiconductor component, and thus, if required, to bridge all of the independent connections with reverse-biasing.

A further application is the already-mentioned use of the zener diode of the zener fuse, which is assisted by the design according to the invention with a central contact. The monitored setting of the zener voltage allows monitored degradation in order to create a low-impedance connection.

In any case, the zener diode Z can be integrated in the BICMOS process flow without any additional masks or method steps, since all of the required production steps are also part of the production process for bipolar transistors and/or CMOS structures.

Although the invention has been described with reference to only one exemplary embodiment, it is not restricted to this. Variations are possible, in particular with respect to the semiconductor material, the process conditions chosen, the dopings and the dopants, and the geometry of the doped regions and zones.

1-20. (canceled)

21. A semiconductor component comprising at least one vertical bipolar transistor and an integrated zener diode, comprising:
a semiconductor substrate;
a region which is buried in the semiconductor substrate and is n-doped;
a centrally arranged, first n-doped zone,
a p-doped region, which has opposite doping to the first n-doped zone in an area adjacent to the surface;
a second n-doped zone, which, while being physically separated from the first n-doped zone, concentrically surrounds the first n-doped zone and the p-doped region located above it, and has an annular shape;
wherein the first and the second n-doped zones are arranged between the buried region and the surface of the semiconductor substrate; and
a first contact to the p-doped region, said first contact being arranged on the surface of the substrate, and a second contact to the n-doped zone, which contacts form two connections of the zener diode.

22. The component as claimed in claim 21,
which has a collector with a collector connection offset laterally with respect to the bipolar transistor, with the collector connection being formed by a further n-doped buried region and by a further n-doped zone which, in terms of the doping depth and the doping strength, are the same as the n-doped buried region and the n-doped zone.

23. The component as claimed in 21,
comprising at least one CMOS structure.

24. The component as claimed in claim 23,
in which the CMOS structure has at least one p-channel transistor with source/drain regions which, in terms of the doping depth and doping strength, are the same as the p-doped region.

25. The component as claimed in claim 21, in which the buried region is heavily doped with antimony.

26. The component as claimed in claim 21, in which the buried region is heavily doped with boron.

27. The component as claimed in claim 21, in which the first and the second n-doped zones are heavily doped with phosphorus.

28. The component as claimed in claim 21, in which the CMOS structure has at least one field-effect transistor, between whose two connections the zener diode is connected such that it forms a short-circuit in the reverse-biased direction.

29. A method for production of a semiconductor component having a vertical bipolar transistor, a CMOS structure and an integrated zener diode, comprising:
manufacturing the bipolar transistor, the CMOS structure and the integrated zener diode parallel on the wafer;
producing a first n-doped zone for the zener diode having opposite doping in an area adjacent to the surface;
producing the n-doped zone together with the connection doping to form a buried region for the electrical connection of the collector of the bipolar transistor, in the same implantation process; and
producing the opposite doping of the n-doped zone together with the doping of the source/drain regions of the CMOS structure.

30. The method as claimed in claim 29, further comprising:
producing a semiconductor substrate having a plurality of n-doped buried regions, which are provided as a sub-collector region of the bipolar transistor and for connection of the anode of the zener diode,
forming at least one n-doped zone over each n-doped buried region, which extends to the surface of the substrate and is intended for connection of the buried region; and
producing a pn junction for the zener diode together with the structuring and doping of the source/drain regions of a p-channel MOS transistor by opposite doping of one of the n-doped regions in an area adjacent to the surface.

31. The method as claimed in claim 29, further comprising:
producing the n-doped regions by means of high-energy implantation of phosphorus, followed by a thermal diffusion step.

32. The method as claimed in claim 29, further comprising:
producing the source/drain regions and the opposite doping of one of the n-doped regions by low-energy implantation of boron, followed by thermal activation of the boron doping.

33. The method as claimed in claim 29, further comprising:
producing the semiconductor substrate by doping, close to the surface, of a wafer with antimony followed by epitaxial deposition of a semiconductor layer above it, with the buried region being produced in the substrate from the initial doping with antimony close to the surface.

34. The method as claimed in claim 29, wherein the doping of the n-doped zone and of the p-doped regions is carried out with the doping profile being monitored, so that the zener diode has a given zener voltage.

35. The method as claimed in claim 29, wherein the implantation steps for production of the doped zones and of the doped regions are carried in a structured manner, using a mask composed of oxide grown on it.

36. The method as claimed in claim 35, wherein for the structuring process during the production of the zener diode, a first n-doped zone is arranged centrally, and a second n-doped zone is arranged concentrically with respect to it, but physically separated from it such that it surrounds the first n-doped zone in an annular shape, and in which the opposite doping is produced only in the central, first n-doped zone.

37. The method as claimed in claim 30, further comprising:
producing silicide contacts on the surface of the substrate in order to make a resistive contact with the zener diode in the area of the annular n-doped zone and in the area of the central p-doped region.

38. The method as claimed in claim 37, wherein the annular n-doped zone is connected by means of a plurality of uniformly distributed silicide contacts.

39. The method as claimed in claim 29, wherein the zener diode is connected via metallic conductors to the CMOS structure and to the bipolar transistor in such a way that at least one CMOS structure is short-circuited by the reverse biased zener diode.
